(19) United States
(12) Patent Application Publication
(10) Pub. No.: US 2016/0095221 A1
(43) Pub. Date: Mar. 31, 2016

(54) INTEGRATION OF ELECTRONIC ELEMENTS ON THE BACKSIDE OF A SEMICONDUCTOR DIE

(71) Applicant: QUALCOMM Incorporated, San Diego, CA (US)

(72) Inventors: Vidhya RAMACHANDRAN, San Diego, CA (US); Urmi RAY, San Diego, CA (US)

(21) Appl. No.: 14/499,151

(22) Filed: Sep. 27, 2014

(51) Int. Cl. H05K 1/18; H05K 3/30; H05K 3/40; H05K 1/11

(52) U.S. Cl. CPC H05K 1/181; H05K 1/115; H05K 3/301; H05K 3/303; H05K 3/4038; H05K 2201/10515; H05K 2201/10166; H05K 2201/10174

(57) ABSTRACT

Systems and methods include a first semiconductor die with a substrate having a first side and a second side opposite to the first side. A first set of electronic elements is integrated on the first side. A second set of electronic elements is integrated on the second side. One or more through-substrate vias through the substrate are used to couple one or more of the first set of electronic elements and one or more of the second set of electronic elements. The through-substrate vias may be through-silicon vias (TSVs) or a through-glass vias (TGVs). The first semiconductor die may be stacked with a second semiconductor die, with the first side or the second side of the first semiconductor die interfacing an active side of the second semiconductor die.

### FIELD OF DISCLOSURE

Disclosed embodiments are directed to integration of electronic elements on backside or a second side of a die which is opposite to an active side or a first side of the die. Exemplary aspects include electronic elements such as thin-film transistors, input/output transistors, diodes, passive devices, etc., on the second side, and through vias such as through silicon vias (TSVs) to connect the first side to the second side.

### BACKGROUND

Advances in the design and manufacture of semiconductor devices have led to shrinking sizes of semiconductor packages, wafers, and dies/chips. As processing needs for modern computer systems, particularly in the area of mobile processing systems increase, there is an ever-increasing demand for integration of a large number of electronic elements on each semiconductor die. Due to limited surface area on the active surface of a semiconductor die, the integration, placement, and routing of electronic elements and components on the semiconductor die presents a well-recognized problem.

For example, conventional integrated circuit designs may use wire-bonding to connect a chip or die, which is mounted upright, to external circuitry or a semiconductor package. Electronic devices/elements/integrated circuit components of the chip are integrated on an active side of the chip. The wire-bonds require input/output (I/O) connections, pads, etc., which are also formed on the active side of the chip, since the chip is mounted face-up on a printed circuit board (PCB), for example. These I/O connections consume relatively large portions of an already limited surface area on the active side.

Another conventional integrated circuit design option involves flip-chip packaging. In a flip-chip, solder balls are formed on a backside of a chip, which is opposite to the active side. Metal connection pads are formed on the active side and connections are made by wire-bonding or through vias through a semiconductor substrate of the chip to the solder balls. Electrical connections to external circuitry are made through the solder balls which may attach to a ball grid array (BGA). However, conventional flip-chip technology also requires placement of I/O connections, metal connection pads to the solder balls, etc., on the active side of the die. Apart from forming the solder balls, the backside of the chip is not utilized for integration of any additional components in conventional flip-chip technology.

Some conventional approaches also include placement of selected components of an integrated circuit or system on a chip (SoC) on a secondary die or chip. For example, I/O ports and/or other electronic elements of an integrated circuit on a first chip may be placed on a second chip in an effort to overcome limitations on surface area on the first chip. However, such solutions introduce additional challenges involved with inter-chip placement and routing, and the interconnections between the two chips may introduce undesirable delays and inefficiencies which may not be tolerated by high performance processing needs.

Additionally, advanced chip design may also involve integration of electronic elements operating in different voltage domains and/or other operating conditions, and the above-discussed approaches do not provide effective solutions to handle such design considerations with shrinking device technologies. Accordingly, there is a need in the art for improved semiconductor device integration techniques which can overcome at least the aforementioned drawbacks in existing solutions.

### SUMMARY

Embodiments of the invention are directed to systems and methods for integration of electronic elements on a backside of a semiconductor die. For example, exemplary systems and methods include a first semiconductor die with a substrate having a first side and a second side opposite to the first side. A first set of electronic elements is integrated on the first side. A second set of electronic elements is integrated on the second side. One or more through-substrate vias through the substrate are used to couple one or more of the first set of electronic elements and one or more of the second set of electronic elements. The through-substrate vias may be through-silicon vias (TSVs) or a through-glass vias (TGVs). The first semiconductor die may be stacked with a second semiconductor die, with the first side or the second side of the first semiconductor die interfacing an active side of the second semiconductor die.

Accordingly, an exemplary aspect includes a semiconductor device comprising a first semiconductor die with a substrate, the substrate comprising a first side and a second side opposite to the first side. A first set of electronic elements is integrated on the first side and a second set of electronic elements is integrated on the second side. One or more through-substrate vias through the substrate couple one or more of the first set of electronic elements and one or more of the second set of electronic elements.

Another exemplary aspect includes a method of forming a semiconductor device, the method comprising: forming a substrate of a first semiconductor die with a first side and a second side opposite to the first side, integrating a first set of electronic elements on the first side, integrating a second set of electronic elements on the second side, and forming one or more through-substrate vias through the substrate for coupling one or more of the first set of electronic elements and one or more of the second set of electronic elements.

Yet another exemplary aspect includes a system comprising a first semiconductor die with a first side and a second side opposite to the first side, a first set of electronic elements integrated on the first side and a second set of electronic elements integrated on the second side. The system further includes means for coupling one or more of the first set of electronic elements and one or more of the second set of electronic elements.

### BRIEF DESCRIPTION OF THE DRAWINGS

The accompanying drawings are presented to aid in the description of embodiments of the invention and are provided solely for illustration of the embodiments and not limitation thereof.

FIG. 1 illustrates a semiconductor die according to exemplary aspects.

FIG. 2 illustrates an aspect pertaining to stacking an exemplary semiconductor die.

FIG. 3 illustrates another aspect pertaining to stacking an exemplary semiconductor die.

FIG. 4 is a flow-chart illustration of an exemplary process for forming a semiconductor die according to aspects of this disclosure.

FIG. 5 is a flow-chart illustration of a method of forming a semiconductor die according to exemplary aspects.

FIG. 6 illustrates a block diagram showing an exemplary wireless communication system in which exemplary aspects may be advantageously employed.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that specific circuits (e.g., application specific integrated circuits (ASICs)), one or more processors executing program instructions, or a combination of both, may perform the various actions described herein. Additionally, the sequences of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Aspects of this disclosure relate to integration of electronic elements and integrated circuit components on at least two sides a semiconductor die, or in other words, two faces of the semiconductor die. The sides and faces may be relative to a substrate of the semiconductor die. As such, an exemplary semiconductor die includes a first side and a second side. Without limitation, the first side can include a conventional active side of a die and the second side can include a conventional backside of the die. The second side or the backside is on the opposite side of the substrate as the first side or the active side. However, departing from conventional designs, the second side of a die in this disclosure includes much more than the conventional backside of semiconductor dies. For example, in aspects of this disclosure, the second side also includes electronic elements or integrated circuit components, in contrast to conventional backsides of semiconductor devices which are limited to aforementioned circuit connections, solder balls, etc.

Accordingly, in this disclosure, the use of the terms “active side” and “backside” are merely utilized for the sake of explanation, in order to provide distinctions of exemplary aspects with conventional designs. It will be understood that the use of the term “active” with reference to the first side is not meant to convey that the second side excludes active components. Thus, in exemplary aspects, both the first and second sides may include electronic elements and integrated circuit components. In other words, exemplary aspects of this disclosure pertain to improvements over conventional designs, where such conventional designs limit integration of electronic elements to a conventional active side and at best utilize the conventional backside of a die for interconnects, solder balls, and the like.

In more detail, the first side of the exemplary semiconductor die includes a first set of one or more electronic elements and the second side includes a second set of one or more electronic elements. As used herein, the term “electronic elements” are meant to include semiconductor devices such as transistors, gates, and other such components of integrated circuits. The term “electronic elements” includes active devices such as transistors, as well as, passive devices such as inductors, capacitors, etc. More importantly, the term “electronic elements” in this disclosure excludes circuit components such as metallization layers, wires, nets, interconnects, solder balls, etc., whose main function is for providing electrical connections. Thus, references to the electronic elements integrated on the first/second sides, for example, are meant to preclude solder balls in the aforementioned conventional flip-chip design, although in exemplary aspects, solder balls may also be integrated in addition to the electronic elements on the first/second sides.

Further, the exemplary semiconductor die also includes through vias for coupling the first side and the second side, and more specifically, for electrically coupling at least one of the first set of electronic elements and at least one of the second set of devices. In one non-limiting example, the semiconductor die may be formed of a silicon substrate as known in the art, in which case the through vias may be through-silicon vias (TSVs). In another non-limiting example, the semiconductor die may be formed of a glass substrate, in which case the through vias may be through-glass vias (TGVs). One of skill in the art will be able to extend aspects of this disclosure to other known technologies for forming the semiconductor dies, as well as the through vias, without departing from the scope of this disclosure. Further, the through vias may include only a part of an electrical connection between an electronic element of the first set and an electronic element of the second set, as there may be metal wires on the first and/or second side to complete the electrical connection. In other words, the through vias need not provide the only interconnection path between the first and second set of electronic elements, and as such, may serve the purposes of electrically coupling the first and second sides in conjunction with metal wires, nets, interconnects as known in the art.

Accordingly, by integrating electronic elements on the second side of the semiconductor die, exemplary aspects exploit additional surface area on the semiconductor die which was previously not utilized on the conventional backside of semiconductor dies. In some non-limiting examples, the second side may be particularly well-suited for electronic elements such as thin-film transistors (TFTs), I/O transistors or gates (which may include I/O TFTs), diodes (including thin-film diodes), passive devices such as parallel plate capacitors, etc. The second side may also include electronic elements related to electrostatic discharge (ESD) protection of the semiconductor die. Accordingly, the second set of electronic elements integrated on the second side of the semiconductor die may include, without limitation, electronic elements made from thin-film technologies, passive devices, and/or ESD elements. Thus, these second set of electronic elements may be moved out of the first side of the semiconductor die in order to relieve congestion on the first side. The first set of electronic elements integrated on the first side may include conventional electronic elements (e.g., conventional transistors such as complementary metal oxide semiconductor (CMOS) transistors) which are part of an integrated circuit or system on a chip. However, the first set of electronic elements is not limited in this manner, and may also include thin-film devices and passive devices in some aspects. The nature and type of electronic elements which are integrated on either the first or second side may be specific to particular design needs and not limited to the above examples. For example, a designer may take into consideration the placement and routing requirements for a particular semiconductor die and apportion electronic elements between the first and second sides which can be coupled by one or more through vias.

In additional aspects, the above semiconductor die with the first and second sides as above may also be stacked with one or more other semiconductor dies. Through silicon stacking (TSS) as known in the art may be used for the stacking. The one or more other semiconductor dies may be conventional semiconductor dies with a conventional active side and a conventional backside, or they may be, without limitation, exemplary semiconductor dies with first and second sides of electronic components as discussed above. Moreover, since the exemplary semiconductor die has electronic elements on both the first and second sides, either the first or the second side may be configured to interface another semiconductor die for the stacking. The above and additional aspects will be further explained with reference now to the figures.

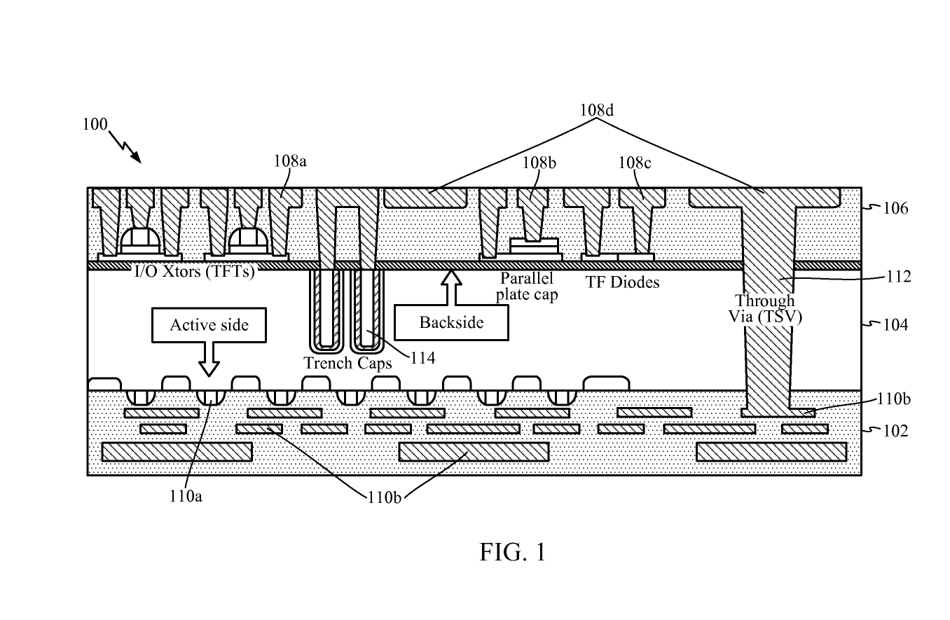

With reference to FIG. 1, semiconductor die 100 is illustrated. Semiconductor die 100 may be designed according to exemplary aspects discussed above, and includes first side 102 and second side 106 formed on either side of substrate 104. As illustrated, first side 102 is representatively shown to include the conventional active side and second side 106 is representatively shown to include the conventional backside of semiconductor die 100. More specifically, first side 102 can include a first set of one or more electronic elements such as transistor 110a (e.g., a CMOS transistor). Moreover, first side 102 can also include one or more metal layers or interconnects 110b which may form interconnections on first side 102 between electronic elements of the first set, although these metal layers or interconnects 110b are not part of the first set of one or more electronic elements. Similarly, second side 106 includes a second set of one or more electronic elements such as I/O transistor 108a (which may be TFTs), parallel plate capacitor 108b and diode 108c (which may be a thin-film diode). Diode 108c may be used for electrostatic discharge (ESD) protection of semiconductor die 100. Second side 106 may also other electronic elements for ESD protection. Further, second side 106 may include one or more metal layers or interconnects 108d which may form interconnections between electronic elements of the second set, but which are not part of the second set of one or more electronic elements.

In the illustrated example, semiconductor die 100 may be a silicon die, and as such, substrate 104 may be formed of silicon. Accordingly, substrate 104 includes one or more through vias representatively illustrated as through-silicon via (TSV) 112. TSV 112 is configured to electrically couple components of first side 102 to components of second side 106. More specifically, TSV 112 may couple one or more metal layers or interconnects 110b on first side 102 and one or more metal layers or interconnects 108d on second side 106. Further, in some aspects, substrate 104 need not be dedicated to only through vias, but may also be used to form additional integrated circuit components such as trench capacitors 114.

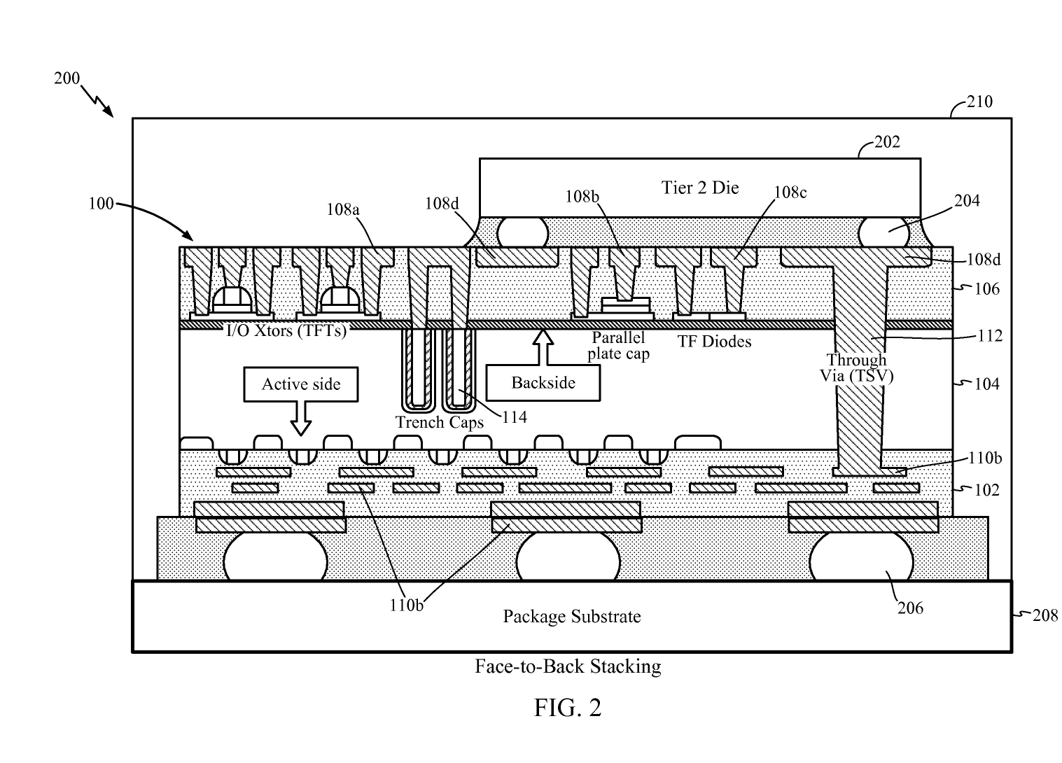

With reference now to FIG. 2, a first aspect pertaining to packaging and stacking of semiconductor die 100 is illustrated. More specifically, semiconductor package 200, as illustrated, includes semiconductor die 100 which may be a first tier or “tier 1” die. Semiconductor die 100 may be stacked with a second die, die 202, which may be a second tier or “tier 2” die. Die 202 may be configured according to exemplary aspects with electronic elements integrated on two opposite sides of die 202 or according to conventional aspects with a conventional active side and a conventional backside, without limitation. The tiered structure is illustrated to represent vertical stacking or three-dimensional (3D) packaging. The stacking may be accomplished based at least in part on the through vias of exemplary semiconductor devices, and as such, are referred to as through-silicon stacking (TSS).

As shown, die 202 is a conventional chip, without limitation, and as such, may be stacked with semiconductor die 100 in a flip-chip manner. Accordingly, the face or active side of die 202 may be interfaced with second side 106 which includes the conventional backside of semiconductor die 100. Thus, this stacking is also referred to as a “face-to-back stacking” where the face of the tier 2 die is stacked with the backside of the tier 1 die, relating the illustrated structure to legacy or conventional terms. More particularly, exemplary semiconductor package includes die 202 stacked to semiconductor die 100 by means of a first ball grid array including solder balls 204. Solder balls 204 are connected to interconnects 108d, which may be coupled to TSV 112. TSV 112 provides coupling of second side 106 to first side 102 of semiconductor die 100, as previously discussed. Thus, TSV 112 provides a means for coupling first side 102 of semiconductor die 100 to die 202 in a TSS fashion. Further, in some aspects, semiconductor die 100 may be further stacked to a third die (not shown) interfacing first side 102, or as in the illustrated aspects, attached to package substrate 208 through a second ball grid array including solder balls 206. Solder balls 206 may couple package substrate 208 to interconnects 110b on first side 102 of semiconductor die 100. Additionally, semiconductor package 200 may include mold 210 to encapsulate both dies, semiconductor die 100 and die 202.

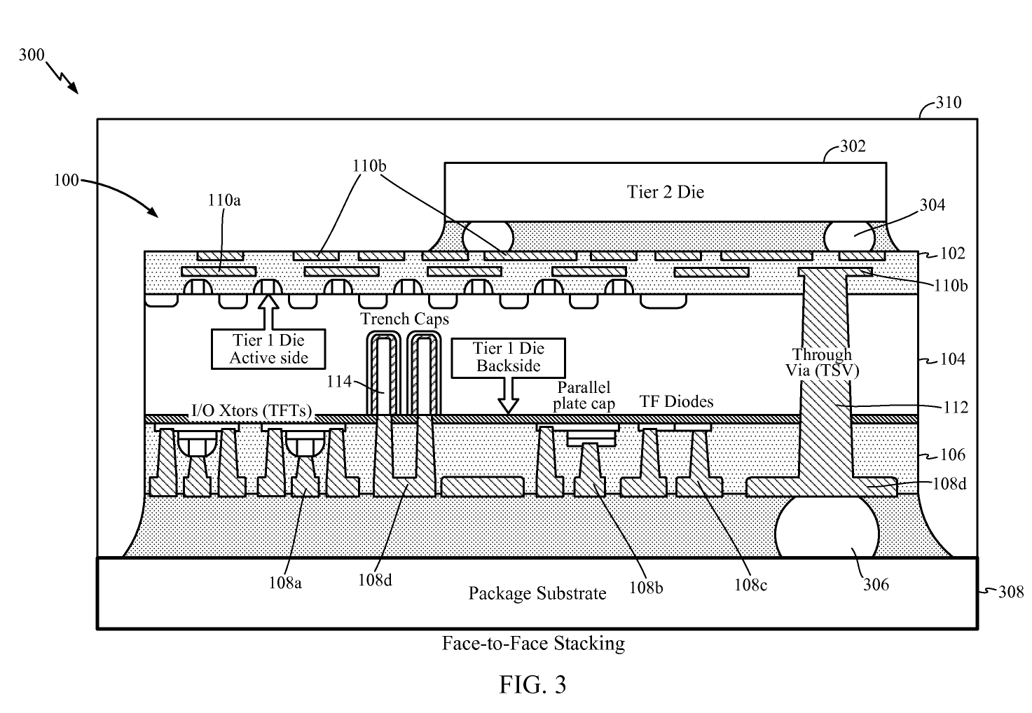

Referring to FIG. 3, a second aspect pertaining to packaging and stacking of semiconductor die 100 is illustrated. Semiconductor package 300 of FIG. 3 is similar in many aspects to semiconductor package 200 of FIG. 2 discussed above. Thus, the explanation of FIG. 3 will omit some of the common aspects between these figures for the sake of brevity. As illustrated, semiconductor package 300 also includes semiconductor die 100 as a “tier 1” die, stacked with a second die, die 302, which may be a “tier 2” die. Once again, die 302 may be configured according to exemplary aspects with electronic elements integrated on two opposite sides of die 302 or according to conventional aspects with a conventional active side and a conventional backside, without limitation. Die 302 may be stacked with semiconductor die 100 in a flip-chip manner.

In contrast to semiconductor package 200 of FIG. 2, semiconductor package 300 of

FIG. 3 shows a “face-to-face stacking.” In more detail, the face or active side of die 302 is interfaced herein with first side 102, which includes the conventional active side of semiconductor die 100. Die 302 is stacked to semiconductor die 100 by means of a first ball grid array including solder balls 304. Solder balls 304 are connected to interconnects 110b, which may be coupled to TSV 112. TSV 112 provides coupling of first side 102 to second side 106 of semiconductor die 100. Thus, TSV 112 provides a means for coupling second side 106 of semiconductor die 100 to die 302 in a face-to-face TSS fashion in this case. Semiconductor die 100 may be further stacked to a third die (not shown) interfacing second side 106, or as in the illustrated aspects, attached to package substrate 308 through a second ball grid array including solder balls 306. Solder balls 306 may couple package substrate 308 to interconnects 108d on second side 106 of semiconductor die 100. Additionally, semiconductor package 300 may also include mold 310 to encapsulate both dies, semiconductor die 100 and die 302.

Thus, as shown in the TSS stacking examples of FIGS. 2-3, TSVs used to couple the first and sides of an exemplary semiconductor die, may also be useful in stacking the exemplary semiconductor die with one or more additional dies in a vertically tiered manner or in a 3D package structure.

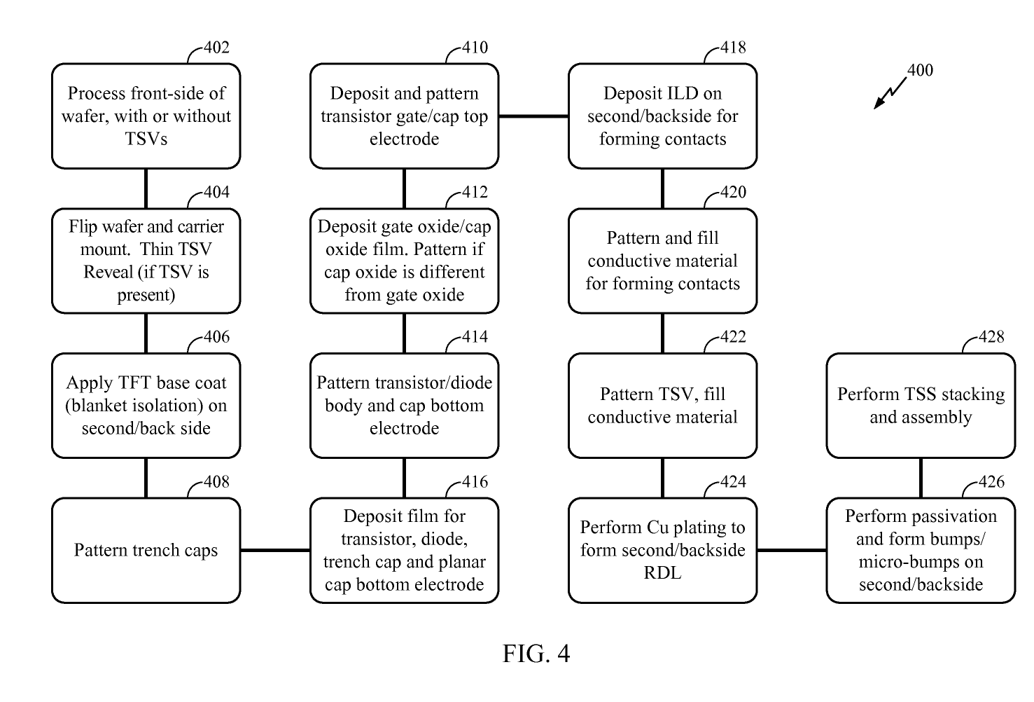

With reference now to FIG. 4, an exemplary process flow for forming a semiconductor die according to exemplary aspects is illustrated. For example, process flow 400 starts with processing a first side (or conventional front/active side, e.g., first side 202) a semiconductor wafer which includes a semiconductor die or chip (e.g., semiconductor die 100) of interest (the processed wafer may or may not include TSVs such as TSV 112 in this step)—Block 402.

Next, the chip may be configured as a flip-chip and carrier mounted; a thin TSV section may be revealed/exposed if a TSV is already present—Block 404. Following this, a thin film transistor (TFT) base coat may be applied on a second side (e.g., second side 106) or backside of the chip, with blanket isolation for forming TFT devices—Block 406. Trenches may be patterned for trench capacitors (e.g., trench capacitors 114) on the second side—Block 408. Deposition and patterning may be performed for electronic elements on the second side, such as, for gates of transistors (e.g., 108a), top electrodes for parallel plate capacitors (108b), etc.—Block 410. If the oxide for the parallel plate capacitors are different from the oxides for the gates of transistors, separate patterning and film deposition may be performed for these different oxides—Block 412. Next the TFT transistors, body of diodes (e.g., 108c) and bottom electrodes for the parallel plate capacitors may be patterned—Block 414. Deposition of the films may be performed for the transistors, diodes, trench capacitors, and parallel plate capacitor's bottom electrode—Block 416. In Block 416, an amorphous transparent conductive oxide (ATCO) film may be used for the bottom electrode in some aspects.

Interlayer dielectric (ILD) may be deposited on the second side or backside to form contacts (e.g., for the face-to-back configuration illustrated in FIG. 2 and described with reference to semiconductor package 200)—Block 418. Patterning and filling of conductive material for forming contacts (e.g., to BGA including solder balls 204) may be performed—Block 420. Patterning for the TSVs on the second side or backside may be performed and conductive material may be filled—Block 422. Cu plating may be performed on the second side or backside to form a redistribution layer (RDL)—Block 424.

Passivation is performed on the second side or back side and bumps/micro-bumps or BGA including solder balls 204 are added—Block 426. The semiconductor die processed as above can now be assembled for stacking (for example in the TSS stacking example of face-to-back stacking in FIG. 2)—Block 428. The semiconductor die can now be stacked with a second die (e.g., die 202), as in the above discussed sections.

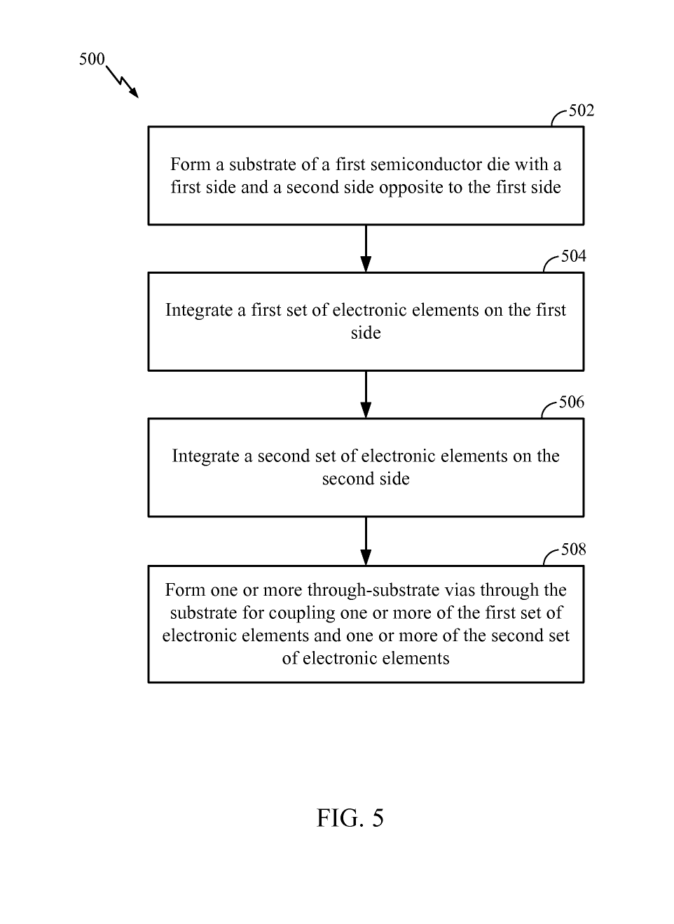

It will be appreciated that embodiments include various methods for performing the processes, functions and/or algorithms disclosed herein. For example, as illustrated in FIG. 5, an embodiment can include a method (500) of forming a semiconductor device, the method comprising: forming a substrate (e.g., 104) of a first semiconductor die (e.g., 100) with a first side (e.g., 102) and a second side (e.g., 106) opposite to the first side—Block 502; integrating a first set of electronic elements (e.g., 110a) on the first side—Block 504; integrating a second set of electronic elements (e.g., 108a, 108b, 108c) on the second side—Block 506; and forming one or more through-substrate vias (e.g., 112) through the substrate for coupling one or more of the first set of electronic elements and one or more of the second set of electronic elements—Block 508.

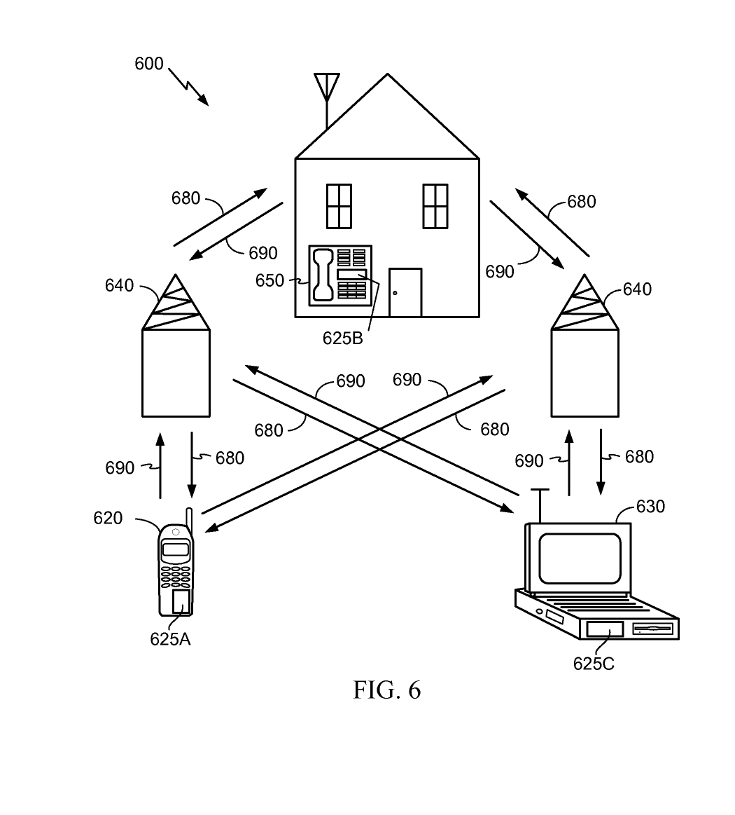

In FIG. 6, a block diagram of an exemplary wireless communication system 600 in which an aspect of the disclosure may be advantageously employed, is illustrated. For purposes of illustration, FIG. 6 shows three remote units 620, 630, and 650 and two base stations 640. It will be recognized that wireless communication systems may have many more remote units and base stations. Remote units 620, 630, and 650 include integrated circuit (IC) devices 625A, 625C and 625B that include the disclosed semiconductor die 100, for example. It will be recognized that other devices may also include the disclosed semiconductor die 100, such as the base stations, switching devices, and network equipment. FIG. 6 shows forward link signals 680 from base station 640 to remote units 620, 630, and 650 and reverse link signals 690 from remote units 620, 630, and 650 to base stations 640.

In FIG. 6, remote unit 620 is shown as a mobile telephone, remote unit 630 is shown as a portable computer, and remote unit 650 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or other devices that store or retrieve data or computer instructions, or combinations thereof. Although FIG. 6 illustrates remote units according to the teachings of the disclosure, the disclosure is not limited to these exemplary illustrated units. Aspects of the disclosure may be also be integrated into a set-top box, a music player, a video player, an entertainment unit, a navigation device, a personal digital assistant (PDA), a fixed location data unit, a mobile phone, a smart phone, or a computer.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for forming a semiconductor die with electronic elements integrated on a backside of the semiconductor die. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

1. A semiconductor device comprising:
a first semiconductor die with a substrate, the substrate comprising a first side and a second side opposite to the first side;
a first set of electronic elements integrated on the first side;
a second set of electronic elements integrated on the second side;
one or more through-substrate vias through the substrate configured to couple one or more of the first set of electronic elements and one or more of the second set of electronic elements;
a second semiconductor die;
a ball grid array comprising solder balls configured to stack the second semiconductor die with the first semiconductor die; and
at least one or more interconnects on the second side, configured to couple one or more of the solder balls to one or more of the second set of electronic elements.

2. The semiconductor device of claim 1, wherein the first set of electronic elements comprise one or more of transistors or active circuit elements.

3. The semiconductor device of claim 1, wherein the second set of electronic elements comprise one or more of input/output devices, thin-film transistors (TFT), passive circuit elements, or electronic elements for electrostatic discharge (ESD) protection of the semiconductor device.

4. The semiconductor device of claim 3, wherein at least one of the passive circuit elements or electronic elements for electrostatic discharge (ESD) protection comprises a thin-film diode.

5. The semiconductor device of claim 1, further comprising one or more interconnects, metal wires, or solder balls integrated on the first side.

6. The semiconductor device of claim 1, wherein the second side of the first semiconductor die is configured to interface an active side of the second semiconductor die, wherein one or more of the interconnects are configured to directly connect one or more of the solder balls to one or more of the second set of electronic elements.

7. The semiconductor device of claim 6, wherein the first semiconductor die and the second semiconductor die are stacked by through silicon stacking (TSS).

8. The semiconductor device of claim 1, wherein the first side of the first semiconductor die is configured to interface an active side of the second semiconductor die, wherein one or more of the interconnects are configured to couple one or more of the solder balls to one or more of the second set of electronic elements through at least the through-substrate vias.

9. The semiconductor device of claim 8, wherein the first semiconductor die and the second semiconductor die are stacked by through silicon stacking (TSS).

10. The semiconductor device of claim 1, wherein the substrate is made of silicon and at least one of the one or more through-substrate vias is a through silicon via (TSV) or a through glass via (TGV).

11. The semiconductor device of claim 1, integrated in a device selected from the group consisting of a set top box, music player, video player, entertainment unit, navigation device, communications device, personal digital assistant (PDA), fixed location data unit, mobile phone, and a computer.

12. A method of forming a semiconductor device, the method comprising:
forming a substrate of a first semiconductor die with a first side and a second side opposite to the first side;
integrating a first set of electronic elements on the first side;
integrating a second set of electronic elements on the second side;
forming one or more through-substrate vias through the substrate for coupling one or more of the first set of electronic elements and one or more of the second set of electronic elements;
stacking a second semiconductor die on the first semiconductor die through a ball grid array comprising solder balls; and
coupling one or more of the solder balls to one or more of the second set of electronic elements through at least one or more interconnects on the second side.

13. The method of claim 12, wherein the first set of electronic elements comprise one or more of transistors or active circuit elements.

14. The method of claim 12, wherein the second set of electronic elements comprise one or more of input/output devices, thin-film transistors (TFT), passive circuit elements, or electronic elements for electrostatic discharge (ESD) protection of the semiconductor device.

15. The method of claim 14, wherein at least one of the passive circuit elements or electronic elements for electrostatic discharge (ESD) protection is a thin-film diode.

16. The method of claim 12, further comprising integrating one or more interconnects, metal wires, or solder balls on the first side.

17. The method of claim 12, comprising interfacing the second side of the first semiconductor die with an active side of the second semiconductor die, with one or more of the interconnects directly connecting one or more of the solder balls to one or more of the second set of electronic elements.

18. The method of claim 17, wherein the stacking comprises through-silicon stacking (TSS).

19. The method of claim 12, comprising interfacing the first side of the first semiconductor die with an active side of the second semiconductor die, with one or more of the interconnects coupling one or more of the solder balls to one or more of the second set of electronic elements through at least the through-substrate vias.

20. The method of claim 19, wherein the stacking comprises through silicon stacking (TSS).

21. The method of claim 12, comprising forming the substrate from silicon, wherein least one of the one or more through-substrate vias is a through-silicon via (TSV) or a through-glass via (TGV).

22. A system comprising:
a first semiconductor die with a first side and a second side opposite to the first side;
a first set of electronic elements integrated on the first side;
a second set of electronic elements integrated on the second side;
means for coupling one or more of the first set of electronic elements and one or more of the second set of electronic elements
a second semiconductor die;
means for stacking the second semiconductor die with the first semiconductor die; and
means for coupling the means for stacking with one or more of the second set of electronic elements.

23. The system of claim 22, wherein the means for stacking comprises means for interfacing the first side or the second side of the first semiconductor die with an active side of the second semiconductor die.

24. The semiconductor device of claim 1, further comprising a trench capacitor formed in the substrate.

25. The method of claim 12, further comprising patterning a trench on the second side and forming a trench capacitor in the patterned trench.
